(19) United States
(12) Patent Application Publication
(10) Pub. No.: US 2004/0153942 A1
(43) Pub. Date: Aug. 5, 2004

(54) Soft input soft output decoder for turbo codes

(76) Inventors: Nathan Shtutman, Ottawa (CA); Mohammad Shahanshah Akhter, Kanata (CA); Robert Wood, Gloucester (CA); Antonio Mascioli, Nepean (CA); Michael Low, Kanata (CA)

Correspondence Address: BORDEN LADNER GERVAIS LLP, WORLD EXCHANGE PLAZA, 100 QUEEN STREET SUITE 1100, OTTAWA, ON, K1P 1J9, CA

(21) Appl. No.: 10/762,728

(22) Filed: Jan. 23, 2004

Related U.S. Application Data
(60) Provisional application No. 60/442,071, filed on Jan. 24, 2003.

(51) Int. Cl. H03M 13/00

(52) U.S. Cl. 714/755

(57) ABSTRACT

A decoder structure is described that can be implemented on an integrated circuit and used to decode turbo codes. A soft input soft output decoder includes a metric aggregator, and a codeword resolver, each of these elements co-operating to resolve manipulated branch and state metric pairs to a codeword in a known set of codewords in accordance with an un-normalized likelihood relationship between the received branch and state metric data pairs and the known set of codewords. The present invention is believed to operate at a relatively lower clock speed and occupy a relatively smaller area than previous structures, thereby consuming less power and incurring lower cost to produce, yet still achieve a substantially similar BER performance. The present invention is suitable for extremely high data rate communications; for example, rates in excess of 100 Mbit/s, such as at 200 MHz and 220 MHz, can be achieved.

### CROSS-REFERENCE TO RELATED APPLICATIONS

The present invention claims priority of U.S. Patent Application Serial No. 60/442,071, filed on Jan. 24, 2003.

### FIELD OF THE INVENTION

The present invention relat□s generally to communication decoders. More particularly, the present invention relates to decoders for turbo codes.

### BACKGROUND OF THE INVENTION

Satellite transmission systems are often used for transmission of data in accordance with standards from the Motion Picture Encoding Group (MPEG). Such transmission typically includes MPEG coding on a transmit side, and MPEG decoding on a receive side. It is also advantageous to employ further coding/decoding to enhance the performance of such systems. For example, when using turbo code components, data is sent through an MPEG coder, then through a turbo coder, then bounced up to a satellite, after which it is received from a satellite and decoded through a turbo decoder and an MPEG decoder. In such a system, a data stream flowing from the turbo coder at the transmit side will typically include a sequence of samples representing a series of transmitted codewords, selected from a known set of codewords. Similarly, data received at the turbo decoder at the receive side will be analyzed in order to determine the likelihood that the received data in the sequence of samples can be mapped to a particular known codeword.

Turbo coding is well known in the art to provide bandwidth and power efficient communications on noisy channels by introducing parity symbols computed by recursive systematic convolutional (RSC) encoders. In many implementations, a pair of RSC encoders are used, with one of the encoders being provided with an interleaved copy of the source data, and the other receiving a non-interleaved copy of the source data. The results of the pair of RSC encoders is provided to a puncturer, which also receives as input a copy of the original data. The parity codes generated by the RSC encoders are punctured with the data symbols in a predetermined pattern, so that a decoder can iteratively process the received data stream and derive an estimate of the original data.

The use of interleavers in front of both the RSC encoders requires that the interleavers be selected so that their interleaving properties, in conjunction with the RSC polynomial, allow the puncturer to generate codewords that have a sufficient distance from each other to allow for error correction.

As noise can never be removed from a physical channel, and increasing the reliability of a communications channel will result in an effective increase in the capacity of the channel, it is desirable to implement a turbo decoder that can achieve low bit error rate (BER) performance at low signal-to-noise ratios (SNR).

In many implementations, the decoding of turbo codes is accomplished through the use of a soft input soft output (SISO) decoder connected in an iterative loop structure such that the output (extrinsic information) is fed back to the SISO in such a way as to iteratively assist it in the decoding process. As the number of decoder iterations increases, its quality improves in such a way as to continually reduce the BER at the decoder output.

FIG. 1 illustrates a conventional serial SISO turbo decoder architecture. Encoded data enters I/Q RAM 10 and is fed into a first SISO 12 as a first data block, the first SISO having one data input. After processing the data in the first SISO 12 as part of a first iteration, the processed data block is fed into memory 14, and subsequently provided as an input to another SISO, such as second SISO 16. In general, the output of any SISO can be stored in the memory 14, and then provided the next SISO, or to any subsequent SISO in the system. In FIG. 1, the second SISO 16 receives at a first input the processed data from the first SISO 12. The first data block that was originally provided to the first SISO 12 is also provided from I/Q RAM 10 to the second SISO 16 at a second input thereof. This process continues through any number of SISOs until the data reaches a final SISO 18. Knowing the coding polynomials used in the encoder, and being able to model the channel being used (e.g. knowing how to approximate the noise in the channel), it is possible to determine the maximum number of iterations that should be necessary to obtain an acceptable result. The last SISO will analyze the last output, as well as the outputs from the previous SISOs, and determine which output is most likely to be the best decoded signal.

One drawback of this serial SISO architecture is that each SISO has to wait for the previous SISO to complete its processing before it can perform its own processing. Of course, once the first SISO has processed the first data block, it can move on to processing a second data block. However, in order to be efficient, in such a system each SISO must perform each iteration in the same amount of time. This is not always the case. As such, it is often necessary to employ some sort of delay factor to overcome any timing problems that may arise from SISO iterations taking different amounts of time.

As the number of desired iterations increases, so does the size of the I/Q RAM buffer, as in serial implementation, the I/Q RAM is repeated. Therefore, a high number of iterations, which results in a lower BER, requires a large buffer size. As such, it is possible to run a decoder using a serial architecture at high frequencies, but the buffer size, and physical size of the decoder, becomes very large. This architecture would involve repeated iterations, each iteration requiring its own block of buffers, resulting in a large buffer size. In order to have a small size, and a system that works at high speed, the same data needs to be provided to all SISOs.

It is clearly desirable to iterate a large number of times in order to make the BER as low as possible. However, this is not always practical in high data rate or power-constrained systems. The physical properties of silicon and the manufacturing process constrain the maximum speed and minimum area required to implement SISO decoders on an integrated circuit. Those skilled in the art will appreciate that it is a challenge for currently-available synthesis tools to produce a design which meets timing constraints in high clock rate designs.

### SUMMARY OF THE INVENTION

It is an object of the present invention to obviate or mitigate at least the following two disadvantages to the implementation of SISO decoders in silicon: that a very high clock speed is required in order to perform a large number of iterations; and that a proportionately large area of silicon is required.

In a first aspect, the present invention provides a soft input soft output (SISO) decoder for use in a hardware based turbo code decoder for receiving a sequence of samples representing a series of transmitted codewords selected from a known set of codewords. The SISO decoder includes: a metric aggregator for receiving and manipulating branch and state metric pairs, the branch and state metric pairs being related to the sequence of samples; and a codeword resolver for resolving the manipulated branch and state metrics pairs to a codeword in the set, in accordance with an un-normalized likelihood relationship between the received branch and state metrics pairs and the known set of codewords. The likelihood relationship can be a likelihood that a particular un-normalized distance from the manipulated branch and state metrics pairs to the codeword, when compared to un-normalized distances to other codewords, indicates that the codeword is correct.

The metric aggregator can include a plurality of D-type flip-flops and a-plurality of adders, each D-type flip-flop of the plurality of D-type flip-flops for receiving one of the branch or state metrics in each pair, and each adder for receiving related branch and state metrics from an associated D-type flip-flop. The D-type flip-flops can be 8 bits in length, and the adders can be of a sufficient size to add 6 bit and 8 bit values.

The codeword resolver can include a hybrid architecture for state-metric calculation. In one embodiment, the codeword resolver can include two MIN* modules at a first level for receiving data associated with aggregated branch and state metrics, the outputs of two MIN* modules being provided to a third MIN* module. In another embodiment, the codeword resolver can include two MIN modules at a first level for receiving data associated with aggregated branch and state metrics, the outputs of two MIN modules being provided to a MIN* module. In a further embodiment, the codeword resolver can include two MIN modules at a first level for receiving data associated with aggregated branch and state metrics, the outputs of two MIN modules being provided to a MIN* module, the MIN* module having a subtractor, a multiplexer controller, and a control module for performing correction operations in accordance with control signals received from the multiplexer controller.

In another aspect, the present invention provides a MIN* operator for use in a soft input soft output (SISO) decoder associated with a turbo decoder, including: a subtractor for receiving data to be decoded, the data associated with aggregated branch and state metrics; a correction module for performing correction operations on data received from the subtractor, the correction module including a pair of lookup tables, and a plurality of multiplexers; and a multiplexer controller for controlling operation of the plurality of multiplexers in the correction module to effect the correction operations in accordance with control signals generated by the multiplexer controller.

The pair of lookup tables can include a positive value lookup table and a negative value lookup table, and each of the pair of lookup tables can have 4 entries, or be of a 4 word length. The multiplexer controller can include a plurality of control units, the plurality of control units in the multiplexer controller preferably being equal to the plurality of multiplexers in the correction module.

In a further aspect, the present invention provides a turbo decoder architecture for hardware implementation including an I/Q RAM, a memory and an extrinsic memory, comprising: a parallel arrangement of a plurality of soft input soft output (SISO) decoders, each SISO including a metric aggregator and a codeword resolver; a memory demapper for providing a data block to each SISO, the data block provided to each SISO being the same data block; and a memory mapper for ensuring that none of the SISOs writes to the extrinsic memory at the same time. The memory demapper can allow the plurality of SISOs to access the I/Q RAM at the same time.

In a yet further aspect, the present invention provides a method of soft input soft output decoding for resolving a sequence of samples to a codeword in a known set of codewords, the method including: receiving a plurality of branch metric and state metric pairs related to the sequence. of samples; aggregating related branch and state metric pairs; and resolving the aggregated branch and state metric pairs to the codeword in the set in accordance with an un-normalized likelihood relationship between the aggregated branch and state metrics pairs and the known set of codewords.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention are described, by way of example only, with reference to the attached Figures, wherein:

FIG. 1A is an illustration of a conventional serial SISO decoder architecture;

FIG. 1B is an illustration of a conventional parallel SISO decoder architecture;

FIG. 2 is an illustration of another parallel SISO decoder architecture;

FIG. 3 is an illustration of a conventional implementation of a state-metric calculator;

FIG. 4 is an illustration of a state-metric calculator according to an embodiment of the present invention;

FIG. 5 is an illustration of a state-metric calculator according to another embodiment of the present invention having a codeword resolver with a hybrid architecture;

FIG. 6 is an illustration of a conventional implementation of a MIN* operator;

FIG. 7 is an illustration of an implementation of a MIN* operator according to an embodiment of the present invention; and

FIG. 8 is an illustration of a state-metric calculator according to a further embodiment of the present invention having a codeword resolver with a hybrid architecture and incorporating the MIN* operator of FIG. 7.

### DETAILED DESCRIPTION

Generally, the present invention describes a design methodology by which a decoder for turbo codes can be implemented in an integrated circuit such that it can operate at a high clock rate, while occupying minimal area.

A decoder structure is described that can be implemented on an integrated circuit and used to decode turbo codes. A soft input soft output decoder includes a metric aggregator, and a codeword resolver, each of these elements co-operating to resolve manipulated branch and state metric pairs to a codeword in a known set of codewords in accordance with an un-normalized likelihood relationship between the received branch and state metric data pairs and the known set of codewords. The present invention is believed to operate at a relatively lower clock speed and occupy a relatively smaller area than previous structures, thereby consuming less power and incurring lower cost to produce, yet still achieve a substantially similar BER performance. The present invention is suitable for extremely high data rate communications; for example, rates in excess of 100 Mbit/s, such as at 200 MHz and 220 MHz, can be achieved.

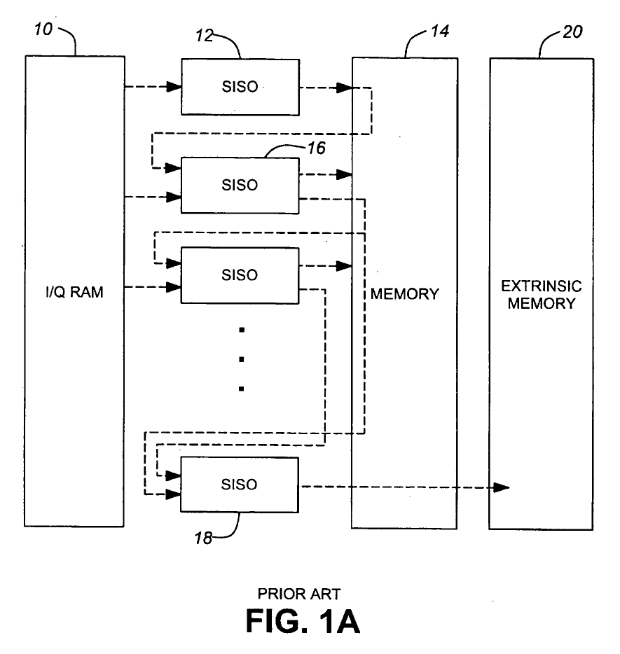

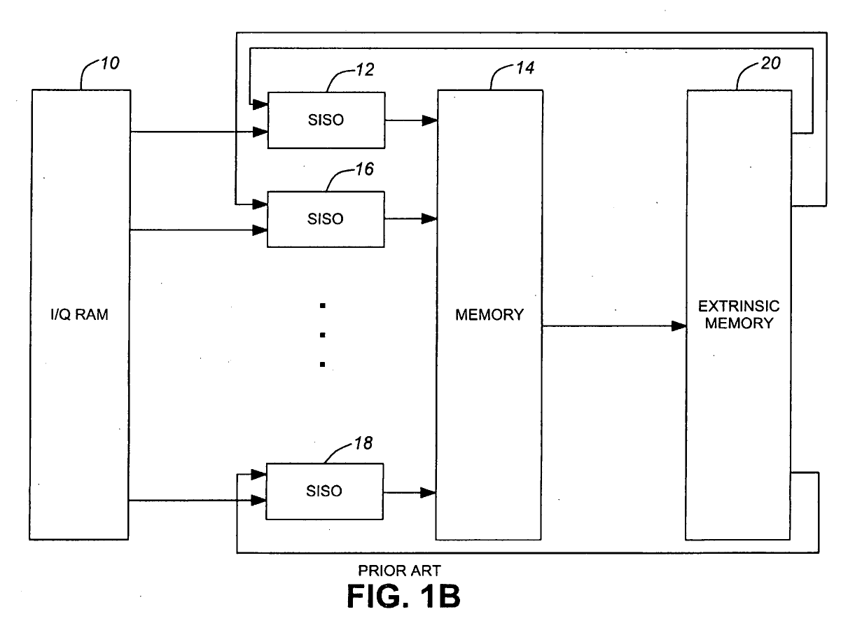

In order to overcome some of the drawbacks of prior serial SISO architectures, as discussed in relation to FIG. 1A, a parallel SISO architecture has been developed. A simple parallel SISO architecture is known, such as from iCODING Technology Inc., and illustrated in FIG. 1B. However, in such a known architecture using parallel SISOs, it is still not possible to write the same information to the different SISOs. Moreover, although such a parallel structure removes some of the latency issues, it becomes difficult to run such a parallel system at high speeds, as is the case with many parallel systems. In order to comply with satellite MPEG transmission standards, it may be necessary to run such a system at a speed of 220 MHz. Note that high speed architecture may also be required in data storage system where GB information need to be stored in a very short amount of time. Also note that for shorter packet size (for example ATM 53 bytes) other than MPEG packet (188 byte), the same decoder change may be used.

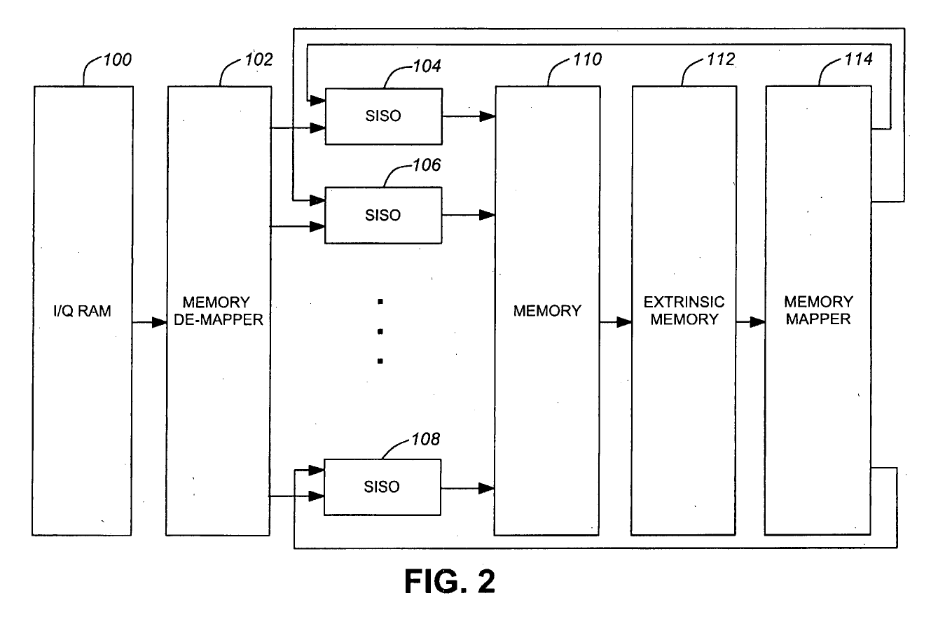

FIG. 2 illustrates a parallel arrangement of M SISOs in a decoder for a turbo code. After a data block passes through I/Q RAM 100, the data is then passed to a memory de-mapper 102. The memory de-mapper 102 provides the same information, such as the same data block, to different SISOs without increasing the size of the buffer, as compared to a serial implementation. As such, each of the SISOs 104, 106, . . . , 108 is able to receive the same data from the memory de-mapper 102. In the diagram of FIG. 2, this same data is advantageously provided at a second input to each SISO. The use of a memory de-mapper 102 allows multiple parallel SISOs to access I/Q RAM in all memory at the same time.

After data is processed in a SISO, and passed to a memory 110 and an extrinsic memory 112, the data can then be passed to a memory mapper 114. The memory mapper 114 performs the reverse operation to the memory de-mapper 102, and ensures that none of the SISOs write to the extrinsic memory at the same time. Data can be output from the SISO, such as to a processor, either from extrinsic memory 112 or memory mapper 114.

Because of the parallel arrangement in FIG. 2 with M NISOs, each SISO need only operate at the clock rate of 1/M compared to the other components. Of course, any number M of SISOs can be used. In order for the structure in FIG. 2 to operate properly at high speed, the memory de-mapper must be designed such that none of the SISOs read from the same address in the I/Q RAM at the same time.

In an exemplary implementation, the Memory Dc-Mapper is 12800 bit pairs in size. The relations that govern its operation in such an embodiment are shown in Table 1.

TABLE 1
Memory De-Mapper Operation

| SISO Index | i (Interleaved Index) | j (Natural Index) |
|---|---|---|
| 1 | k + 0 | ([k % 80] + k*80) % 12800 |
| 2 | k + 3200 | ([k % 80] + k*80) % 12800 |
| 3 | k + 6400 | ([k % 80] + k*80) % 12800 |
| 4 | k + 9600 | ([k % 80] + k*80) % 12800 |

In Table 1, k is an index that ranges from 0 to 3199. The “%” operation is a modulo operation, such as the modulo 80 operation. Since it is not necessary to have a large RAM, it is possible to use simple logic. The modulo 80 operation gives a good balance between size and performance.

To summarize FIG. 2, this arrangement provides a turbo decoder architecture for hardware implementation including an I/Q RAM, a memory and an extrinsic memory, comprising: a parallel arrangement of a plurality of soft input soft output (SISO) decoders, each SISO including a metric aggregator and a codeword resolver; a memory demapper for providing a data block to each SISO, the data block provided to each SISO being the same data block; and a memory mapper for ensuring that none of the SISOs writes to the extrinsic memory at the same time. The memory demapper can allow the plurality of SISOs to access the I/Q RAM at the same time.

Tail-biting turbo codes are known to have desirable BER performance attributes. In a particular example of the decoder illustrated in FIG. 2 designed to decode a tail-biting turbo code, four SISOs are used, i.e. M=4. In such an implementation, the decoder can be described in further detail as follows. Each SISO operates on a sub-frame with a size of about one quarter the original frame. Also, each SISO is supplied at the beginning and end with an overlap into the two adjacent sub-frames, equal to the traceback window length. Thus, the forward state metrics can be initialized with one window of data from the previous sub-frame, and the reverse state metrics are initialized with one window of data from the next sub-frame. Because of the tail-biting property of the turbo code, this is true even for the first and last sub-frames.

The parallel SISO architecture of FIG. 2 therefore advantageously provides a memory de-mapper and a memory mapper, in order to provide the same information to parallel SISOs, and to prevent each of the SISOs from writing to extrinsic memory at the same time. This structure provides enhanced efficiency in terms of smaller size. Of course, having achieved a smaller size, it is desirable to investigate whether any further improvements are potentially available with respect to decoder implementation.

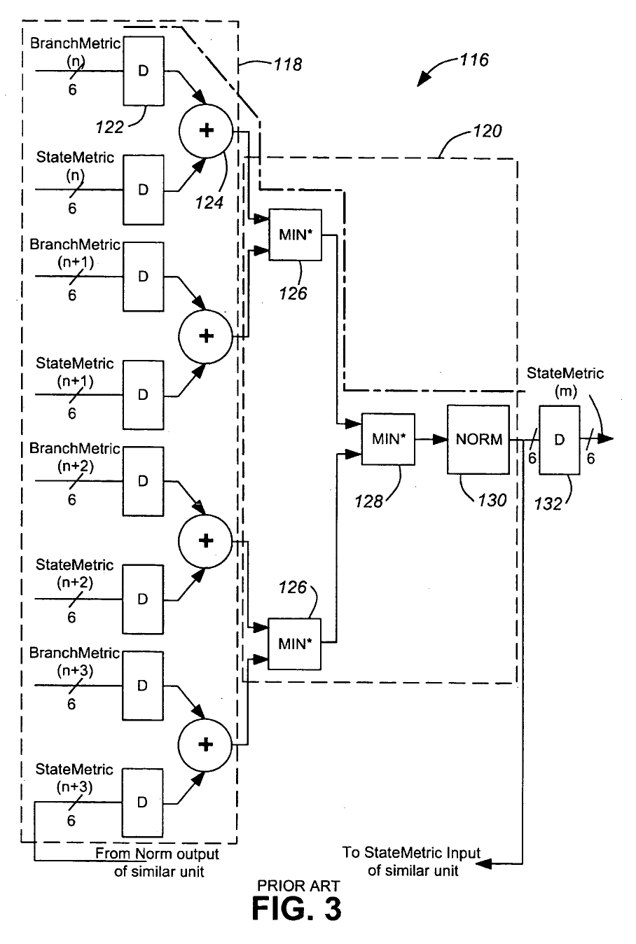

FIG. 3 is an illustration of a conventional implementation of a state-metric calculator, such as can be found in a decoder. Each SISO preferably includes a state metric calculator (SMC) 116 , for performing a state metric calculation, which is commonly implemented as shown in the embodiment in FIG. 3. Although embodiments will be described herein with respect to a SISO including a state metric calculator having certain characteristics, it is to be understood that reference can simply be made in terms of the same embodiments to a SISO itself having the same characteristics. As mentioned earlier, a data stream flowing from a turbo coder at a transmit side of a system will typically include a sequence of samples representing a series of transmitted codewords, selected from a known set of codewords. Similarly, data received at the turbo decoder at the receive side will be analyzed in order to determine the likelihood that the received data in the sequence of samples can be mapped to a particular known codeword.

The state metric calculator 116 includes a metric aggregator 118 and a codeword resolver 120. In use, the SMC 116, or the SISO itself, receives a sequence of samples representing a series of transmitted codewords, selected from a known set of codewords. The metric aggregator 118 receives and manipulates pairs of branch and state metrics. The plurality of branch metric and state metric pairs are related to the sequence of samples, in a manner that is well known to those skilled in the art. The codeword resolver 120 resolves the manipulated metric pairs to a codeword in the set.

Described in further detail, in the critical path of SMC 116, indicated by the dashed line, branch metric and state metric enter the metric aggregator 118. The data propagates though a D-type flip-flop 122, and are summed at an adder 124. The D-type flip-flop 122 is typically 6 bits in length. There is a plurality of branch metric and state metric pairs, each metric containing data, each being summed at its own adder. The summed output of adjacent adders is provided at an output of the metric aggregator 118 to an input of the codeword resolver 120. In the codeword resolver 120, data is passed to one of MIN* modules 126 at a first level, then to a second MIN* module 128 at a second level. The output of the second MIN* module 128 is provided to a NORM module 130. The output of the NORM module 130 is provided at the output of the codeword resolver 120 to a D-type flip-flop .

As illustrated in FIG. 3, the output of the NORM module can be provided to a state metric input of a similar SMC used in a SISO. Similarly, the state metric input can be provided from a NORM output of a similar SMC used in a SISO. Each of the modules in FIG. 3 is well known to those of skill in the art. The MIN* module is a variation of the known MIN module, and performs correction operations, either using a lookup table or by performing a complex calculation. The NORM module is a subtraction normalization module that performs normalization mapping to shift the spectral distribution of an input and normalize the magnitude of the output state metric within a predefined range. The concept of subtraction normalization, such as performed by the NORM module, will be referred to hereinafter simply as “normalization”. Consequently, the output of the codeword resolver 120 in FIG. 3 is said to represent a normalized relationship between the received sequence of samples and the known set of codewords.

The state-metric calculation of FIG. 3 is for use with a known parallel structure without a memory mapper or memory de-mapper, such as in FIG. 1B. However, as mentioned earlier, with such systems known in the prior art, there was a problem with timing. With respect to the prior art system of FIG. 3, it was found that it could not be operated at 200 MHz, and further did not work well at the 220 MHz target required for standards compliance.

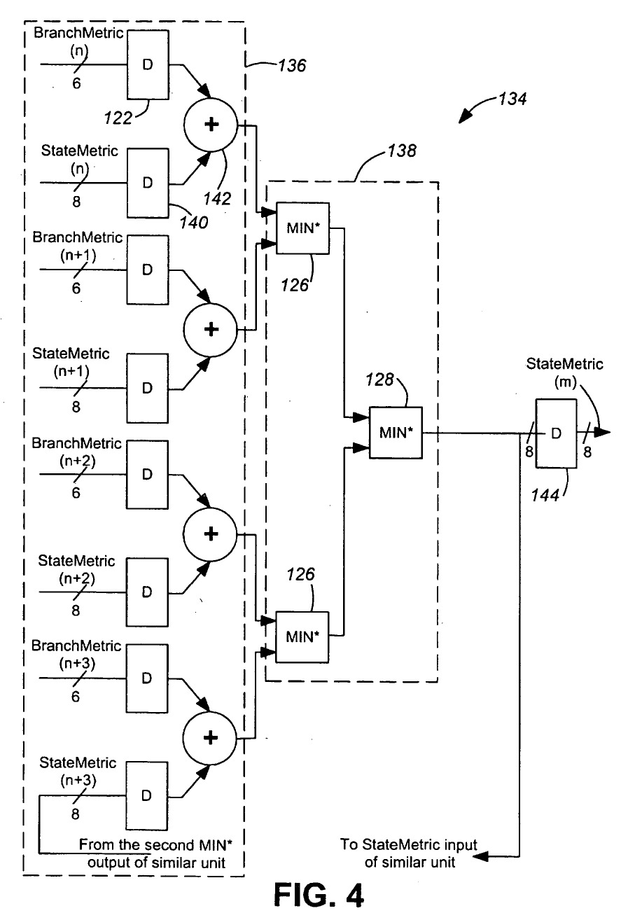

FIG. 4 is an illustration of a method of state-metric calculation according to an embodiment of the present invention, illustrated in the context of a state metric calculator 134. In use, the SMC 134, or the SISO itself, receives a sequence of samples representing a series of transmitted codewords, selected from a known set of codewords.

The state metric calculator 134 includes a metric aggregator 136, and a codeword resolver 138. The metric aggregator 136 is similar to the metric aggregator 118 of FIG. 3, with some differences. For the metric aggregator 136, when receiving and manipulating pairs of branch and state metrics, a branch metric of 6 bit length is received, while a state metric of 8 bit length is received. Accordingly, the D-type flip-flops 140 for receiving the state metric are now 8 bits in length. Similarly, the adders 142 are larger, permitting summation of 6 bit branch metric and 8 bit state metric.

In the embodiment shown in FIG. 4, the codeword resolver 138 resolves the manipulated metric pairs to a codeword in the known set of codewords. However, a different method is employed than the subtraction normalization of the prior art approaches. In the known subtraction normalization, the minimum of all state metrics, calculated on the previous cycle, is computed and subtracted from the output of the last MIN* module. The codeword resolver 138 includes a plurality of MIN* modules 126 at a first level, and a second MIN* module 128 at a second level, similar to the codeword resolver 120 of FIG. 3. This can alternatively be described as the second MIN* module 128 receiving information from the two MIN* modules 126 in a trellis formation. However, no subtraction is performed in the codeword resolver 138 according to an embodiment of the present invention, as is evidenced by the lack of a NORM module when compared to the codeword resolver 120 of FIG. 3. The output of the codeword resolver 138 is provided to a D-type flip-flop, which is 8 bits in length.

Describing the method associated with FIG. 4 in another manner, the present invention provides a method of soft input soft output decoding for resolving a sequence of samples to a codeword in a known set of codewords, the method including: receiving a plurality of branch metric and state metric pairs related to the sequence of samples; aggregating related branch and state metric pairs; and resolving the aggregated branch and state metric pairs to the codeword in the set in accordance with an un-normalized likelihood relationship between the aggregated branch and state metrics pairs and the known set of codewords.

The codeword resolver 138 can be described as resolving manipulated metric pairs to a codeword in the set, in accordance with an un-normalized likelihood relationship between the received sequence of samples and the known set of codewords. In the case where distances from known codewords are determined, this likelihood is essentially the likelihood that a particular un-normalized distance from a manipulated branch and state metrics pair to the codeword, when compared to un-normalized distances to other codewords, indicates that the resolved codeword is correct. In this likelihood determination, it is not necessarily the smallest, or minimum, distance from the manipulated metric pairs to a codeword that determines whether it is most likely the correct one. Observed patterns from previously received data can also be examined to determine whether a distance from a codeword is similar to previously observed known distances from other codewords. As such, a manipulated metric pair may be closer to a first codeword, but may fall in line with a known pattern of distances with respect to a second codeword, and may then be resolved to the second codeword, because of the increased likelihood that it is correct.

Previous SMC implementations for parallel structures use a NORM module. The NORM module is typically required to achieve a lower BER. The common belief of those skilled in the art is that the NORM module is required in order to obtain useful data results at the output state metric. In an SMC architecture according to an embodiment of the present invention, the result of the MIN* operation is allowed to wrap around its maximum value, if necessary. The advantage achieved is the total removal of NORM unit from the critical path. the penalty is that more bits are required to represent the state metric value (8 instead of the original 6). Using 8 bits provides sufficient bit precision to represent the un-normalized value. As a result, wider adders and other arithmetic logic are required on the critical path. However, the contribution of wider logic delay is much smaller than the delay reduction achieved by the removal of NORM unit.

Therefore, an unexpected result of the removal of the NORM module, preferably combined with the use of 8 bits for the state metric value and a wider summation module, is that the total delay of the critical path is significantly reduced. A smaller die size is also achieved with the removal of the NORM module. The faster operation and smaller physical size in implementation is seen to be worth any potential increase in BER due to the removal of the normalization operation. With more powerful processors continually becoming available, it is possible to shift some processing power to an external processor, and remove the normalization calculation from within the state metric calculation. Any issues introduced by the lack of the NORM module can generally be handled in post-processing, or at another network layer, such as in MPEG decoding.

In summary, the embodiment of FIG. 4 can be described as a soft input soft output (SISO) decoder for use in a hardware based turbo code decoder for receiving a sequence of samples representing a series of transmitted codewords selected from a known set of codewords. The SISO decoder includes: a metric aggregator for receiving and manipulating branch and state metric pairs, the branch and state metric pairs being related to the sequence of samples; and a codeword resolver for resolving the manipulated branch and state metrics pairs to a codeword in the set, in accordance with an un-normalized likelihood relationship between the received branch and state metrics pairs and the known set of codewords. The likelihood relationship can be a likelihood that a particular un-normalized distance from the manipulated branch and state metrics pairs to the codeword, when compared to un-normalized distances to other codewords, indicates that the codeword is correct.

In the embodiment illustrated in FIG. 4, the state metric calculation involves three standard MIN* operations. While such an implementation is acceptable for many implementations, including 200 MHz, it was still found to be somewhat lacking in terms of operation at 220 MHz. Therefore, an improvement is desired to permit operation at a wider range of frequencies, and to permit compliance with satellite transmission standards.

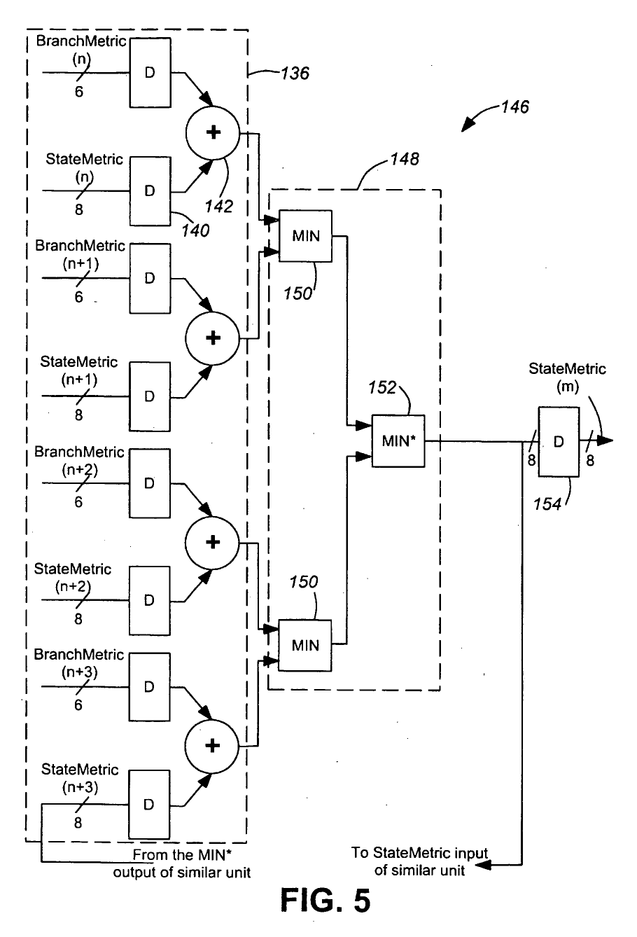

FIG. 5 is an illustration of a state-metric calculator according to another embodiment of the present invention having a codeword resolver with a hybrid architecture. In use, SMC 136, or the SISO itself, receives a sequence of samples representing a series of transmitted codewords, selected from a known set of codewords. The state metric calculator 146 includes the metric aggregator 136, and a codeword resolver 148. The metric aggregator 136 is the same as the metric aggregator 136 of FIG. 4. The codeword resolver 148 resolves the manipulated metric pairs to a codeword in the known set of codewords, in accordance with an un-normalized likelihood relationship between the received sequence of samples and the known set of codewords. The codeword resolver 148 includes a plurality of MIN modules 150 at a first level, for example two MIN modules in FIG. 5. The codeword resolver 148 includes, at a second level, a MIN* module 152. The output of the codeword resolver 148 is provided to a D-type flip-flop 154, which is 8 bits in length.

In the architecture of FIG. 5, in contrast to the embodiment of FIG. 4, each of the two MIN* operations on the first level in FIG. 4 is replaced by standard MIN modules in FIG. 5. This reduces the critical path delay, since the MIN module is much faster than the MIN* module, i.e. has a smaller delay. The penalty is a slight increase in BER.

In FIG. 5, one MIN* module is used, along with two regular MIN modules, which are faster and smaller than the MIN* modules. Alternatively, it is possible to use two MIN* operations in the first level, and one regular MIN module in the second level, which still has each data block going through a MIN* and MIN module. Experimental results showed that the use of MIN* in this arrangement did not affect the performance much (about a 0.05 dB degradation).

To summarize the embodiments of FIGS. 3-5, the metric aggregator can include a plurality of D-type flip-flops and a plurality of adders, each D-type flip-flop of the plurality of D-type flip-flops for receiving one of the branch or state metrics in each pair, and each adder for receiving related branch and state metrics from an associated D-type flip-flop. The D-type flip-flops can be 8 bits in length, and the adders can be of a sufficient size to add 6 bit and 8 bit values. The codeword resolver can include a hybrid architecture for state-metric calculation. In one embodiment, the codeword resolver can include two MIN* modules at a first level for receiving data associated with aggregated branch and state metrics, the outputs of two MIN* modules being provided to a third MIN* module. In another embodiment, the codeword resolver can include two MIN modules at a first level for receiving data associated with aggregated branch and state metrics, the outputs of two MIN modules being provided to a MIN⊃ module.

As is well known, the MIN* operation is simply the MIN module, plus a correction. Although desired and sometimes necessary, the correction portion of the MIN* operation takes time, since it involves using a lookup table, or performing a series of complex calculations. The lookup correction table values are typically determined by simulation, real-world testing, and knowing what data is being sent and received.

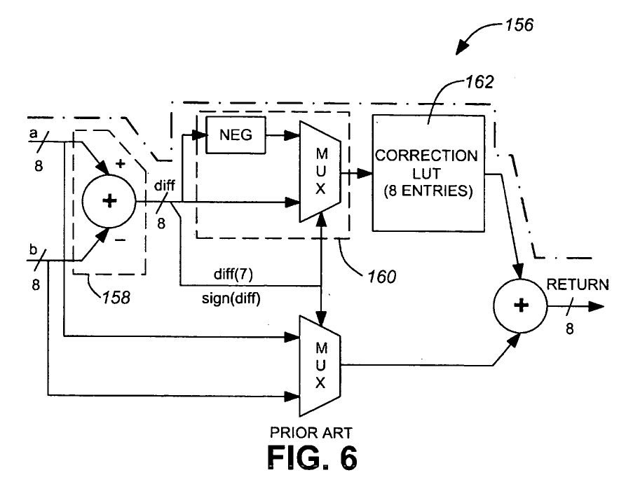

FIG. 6 is an illustration of a conventional implementation of a MIN* module, or operator, 156. In the critical path of FIG. 6, shown by the dashed line, data propagates through a subtraction unit 158, an absolute value unit 160, an 8-word correction lookup table (LUT) 162, and a final adder. As mentioned earlier, the use of the lookup table takes time, especially with the 8-word implementation. Moreover, the absolute value unit requires multiplexer control signals in order to properly manipulate the data before it is sent to the LUT. Therefore, it would be advantageous to have a substantially similar behaviour as the MIN* module, but one that is faster.

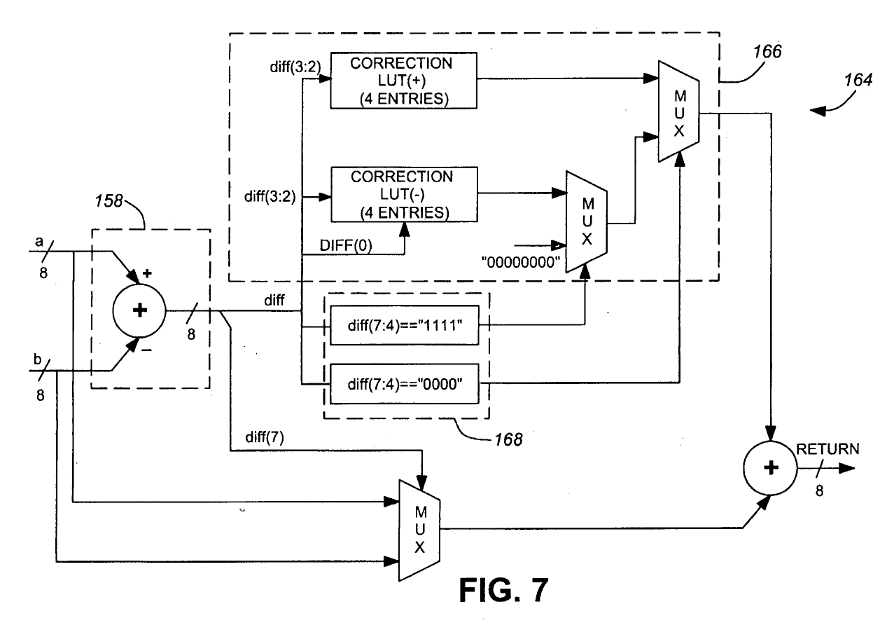

FIG. 7 is an illustration of an implementation of a MIN* operator according to an embodiment of the present invention. The implementation of the MIN* module, or operator, in FIG. 7 is a modification of the MIN* operator of FIG. 6. The embodiment shown in FIG. 7 can be derived from the original MIN* operation as follows: first, the original 8-word LUT shown in FIG. 6 is expanded to a 16-word LUT covering the range of diff(3:0) from −16 to +15. This is split into two separate 8-word LUTs (one for positive difference and another for negative difference). This permits the correction value to be calculated before the sign of the diff value is ready. When the sign is ready, it is used to select the correct LUT output. Finally, the 8-word LUT is decimated by two to obtain a 4-word lookup table. This is possible since through experimental observations it was found that pairs of entries map to the same output value, except one pair of input entries. Because of this, an additional control was needed, which is implemented, for example, in the diff(0) portion of FIG. 7. The smaller LUTs incur a smaller critical path delay, at the expense of an insignificant increase in BER.

Examining FIG. 7 in further detail, a MIN* module 164 according to an embodiment of the present invention is provided. The MIN* module 164 includes the subtractor 158, which is the same as the subtractor 158 of FIG. 6. However, the modified MIN* module 164 includes a correction module 166 and multiplexer controller 168. This is in contrast to the absolute value unit 160 and the 8-word correction lookup table (LUT) 162 of the conventional MIN* module 156 of FIG. 6. The correction module 166 includes two 4-entry, or 4-word, correction LUTs, as described above. Since the two LUTs are for positive and negative values, respectively, there is no longer a need for an absolute value unit. Of course, the division of LUTs need not necessarily be on the basis of positive and negative values, though this is an attractive implementation. For instance, two tables could be provided, one for processing odd values and one for processing even values. In such a case, the reduction of LUT size may not be the same as the positive and negative separation, due to differences in output correlations. The correction module 166, in the embodiment of FIG. 7, also includes two multiplexers, which each receive information from one of the two LUTs, with the second multiplexer also receiving the output of the first multiplexer. The correction module performs lookups in the LUTs in accordance with multiplexer control signals, which are received from the multiplexer controller 168. The multiplexer controller 168 provides control signals to control the multiplexers of the correction module 166. Preferably, the multiplexer controller 168 includes a plurality of control units to provide such control signals, and more preferably the plurality of control units in the multiplexer controller 168 is equal to the plurality of multiplexers in the correction module. 166 This is in accordance with the discussion above. The correction module 166 is essentially a replacement for the known LUT of FIG. 6 and provides pairwise entries and correction.

Therefore, the modified MIN* module of FIG. 7 according to an embodiment of the present invention can be said to operate as follows. First, a subtraction operation is performed. A correction lookup is then performed in two 4-word correction LUTs and the lookup results are multiplexed in accordance with multiplexer control signals from the multiplexer controller. A final adding operation is also performed. This is in contrast to the MIN* module of FIG. 6, in which case an initial subtraction is performed, but then an absolute value operation requiring multiplexer control is performed. A correction lookup in an 8-word correction LUT is then performed, followed by a final adding operation. The operations performed by the modified MIN* module of FIG. 7 are performed faster than those of the conventional MIN* module of FIG. 6.

The MIN* module 164 of FIG. 7 according to an embodiment of the present invention is preferably used in a parallel SlSO decoder architecture, such as shown in FIG. 2. In the modified MIN* of FIG. 7, a difference is calculated in order to determine a correction. It is assumed that the difference is always less than 16. For all such cases, we calculate an appropriate correction from the LUTs; for all other cases we set a correction to 0. Although the modified MIN* implementation of FIG. 7 involves some increased LUT size, the advantages obtained outweigh the increased size/time. This implementation also uses smaller LUTs and smaller MUXes, as compared to the conventional MIN* implementation, since operations are now performed on 4-word values as opposed to 8-word values.

To summarize the MIN* implementation of the embodiment of FIG. 7, a MIN* operator is provided for use in a soft input soft output (SISO) decoder associated with a turbo decoder, including: a subtractor for receiving data to be decoded, the data associated with aggregated branch and state metrics; a correction module for performing correction operations on data received from the subtractor, the correction module including a pair of lookup tables, and a plurality of multiplexers; and a multiplexer controller for controlling operation of the plurality of multiplexers in the correction module to effect the correction operations in accordance with control signals generated by the multiplexer controller. The pair of lookup tables can include a positive value lookup table and a negative value lookup table, and each of the pair of lookup tables can have 4 entries, or be of a 4 word length. The multiplexer controller can include a plurality of control units, the plurality of control units in the multiplexer controller preferably being equal to the plurality of multiplexers in the correction module.

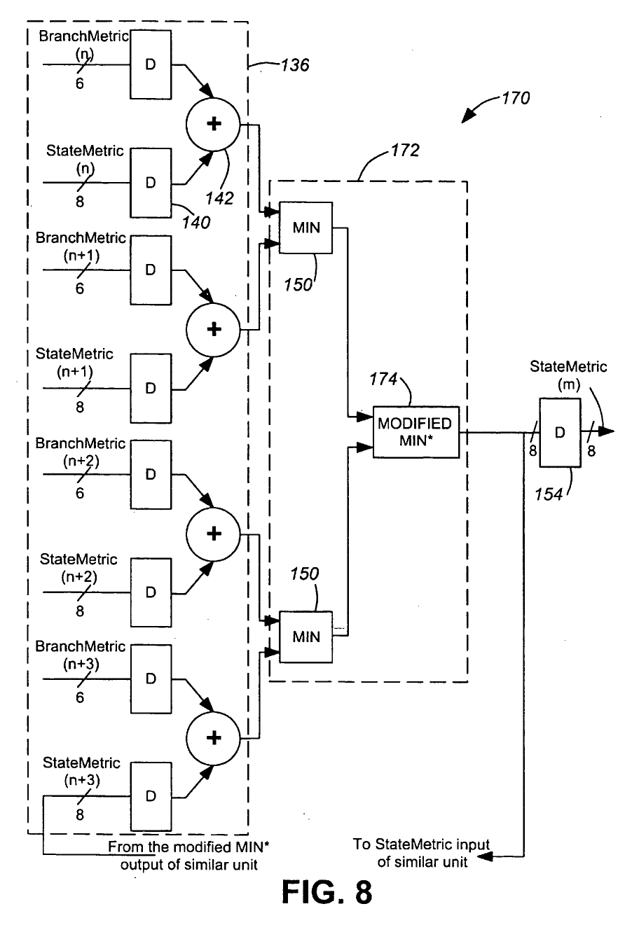

FIG. 8 is an illustration of a state-metric calculator according to a further embodiment of the present invention having a codeword resolver with a hybrid architecture and incorporating the MIN* operator 164 of FIG. 7. A state metric calculator 170 includes the metric aggregator 136, and a codeword resolver 172. In use, SMC 170, or the SISO itself, receives a sequence of samples representing a series of transmitted codewords, selected from a known set of codewords. The metric aggregator 136 is the same as the metric aggregator 136 of FIG. 4 and FIG. 5. The codeword resolver 172 includes a plurality of MIN modules 150 at a first level, and a modified MIN* module 164 at a second level. The difference between FIG. 5 and FIG. 8 is that the conventional MIN* module 152 has been replaced by the modified MIN* module 164 according to an embodiment of the present invention. Similar to FIG. 5, the codeword resolver 172 resolves the manipulated metric pairs to a codeword in the known set of codewords, in accordance with an un-normalized likelihood relationship between the received sequence of samples and the known set of codewords. As in FIG. 5, the output of the codeword resolver 172 is provided to a D-type flip-flop 154, which is 8 bits in length. Therefore, according to the embodiment of FIG. 8, the codeword resolver can include two MIN modules at a first level for receiving data associated with aggregated branch and state metrics, the outputs of two MIN modules being provided to a MIN* module, the MIN* module having a subtractor, a multiplexer controller, and a control module for performing correction operations in accordance with control signals received from the multiplexer controller.

Using the information above relating to embodiments of the present invention, it is now possible to consider the implications of the use of such embodiments as they relate to implementation thereof in silicon, or any other substrate. An equation for the area of the SISO, as used in a DVB-S2 Call for Proposals is shown below, with a modification that takes into account the three additional MAX* operations required to calculate the parity log-likelihood ratios need for Pragmatic TCM

SISO=Memory(10·(m+1)·B_{S}·2^{m})+3500└2·2^{m}·(2^{k}−1)+2^{k+m}−1+3┘

The equation for the overall area of an iterative decoder, such as in FIG. 1, is given below. It has been modified to ensure that the extrinsic data memory is not more than 524 kbits. Furthermore, the N_{I} term has been moved outside of the Memory expression in order to obtain a more realistic value.

Iterative Decoder=η₁·N_{I}·Memory(Sₘₐₓ·2·B_{IQ})+η₂·N_{I}·[2·SISO+2·Memory(N·Bₑ)]

Since the number of bits in the Forney interleaver is greater than 524 kbits, the area of this memory was estimated using the following approximation:

Memory(x)=2·Memory(x/2)

In one possible embodiment, using a commonly implemented pipelined architecture, the area required to implement the decoder is shown in Table 2. The total area is 13.97 mm² for an iterative, or serial, SISO architecture such as in FIG. 1.

TABLE 2
Complexity of decoder using pipelined architecture

| | | | |
|---|---|---|---|
| Code memory | m | 3 | |
| Number of | k | 2 | |
| branches | | | |
| Reuse factor 1 | η1 | 0.5 | |
| Reuse factor 2 | η2 | 0.5 | |
| State metric width | Bs | 12 | bits |
| Sample width | Biq | 6 | bits |
| Extrinsic width | Be | 8 | bits |
| Number of | Ni | 8 | |
| iterations | | | |
| Bits per frame | N | 25600 | bits |
| Symbols per | Smax | 25600 | symbols |
| frame | | | |
| max* area | | 3500 | um\hat{ }2 |
| Traceback | | 3840 | bits |
| memory | | | |
| | | 24230.54 | um\hat{ }2 |
| SISO logic: | | 287000 | um\hat{ }2 |
| SISO total: | SISO | 311230.54 | um\hat{ }2 |
| Sample memory: | | 307200 | bits |
| | | 913665.95 | um\hat{ }2 |
| Extrinsic memory: | | 204800 | bits |
| | | 634663.69 | um\hat{ }2 |

| | | | |
|---|---|---|---|
| Total | Iterative Decoder | 11221817.61 | um\hat{ }2 |
| | | 11.22 | mm\hat{ }2 |

| | | |
|---|---|---|
| RS decoder area | 0.5 | mm\hat{ }2 |
| Outer interleaver: | 772310 | bits |
| | 2248781.95 | um\hat{ }2 |

| | | |
|---|---|---|
| Inner and Outer code total: | 13.97 | mm\hat{ }2 |

A preferred embodiment implements the parallel architecture shown in FIG. 2.

This requires the following elements:

1. Two banks of extrinsic memory, each of size N, storing soft extrinsic values with Bₑ bits (if a dual port memories are used then only a single bank is needed).

2. A double buffer for the channel received samples, sufficient to store B_{IQ} bits for each I or Q sample and Sₘₐₓ maximum symbols per transmission frame.

3. A total of M SISO decoders.

The area of the decoder is then given by:

Iterative Decoder=2·Memory(N·B₃)+2·Memory(Sₘₐₓ·2·B_{IQ})+M·SISO

For a maximum throughput of 110 Mbit/s, a total of 4 SISOs is sufficient. A summary of the area calculation is shown in Table 3. The result is 7.09 mm²—almost half that required by the pipelined architecture.

TABLE 3
Complexity of decoder using parallel architecture

| | | | |
|---|---|---|---|
| Code memory | m | 3 | |
| Number of | k | 2 | |
| branches | | | |
| Number of SISOs | M | 4 | |
| State metric width | Bs | 12 | bits |
| Sample width | Biq | 6 | bits |
| Extrinsic width | Be | 8 | bits |
| Number of | Ni | 8 | |
| iterations | | | |
| Bits per frame | N | 25600 | bits |
| Symbols per | Smax | 25600 | symbols |
| frame | | | |
| max* area | | 3500 | um\hat{ }2 |
| Traceback | | 3840 | bits |
| memory | | | |
| | | 24230.54 | um\hat{ }2 |
| SISO logic: | | 287000 | um\hat{ }2 |
| SISO total: | SISO | 311230.54 | um\hat{ }2 |
| Sample memory: | | 307200 | bits |
| | | 913665.95 | um\hat{ }2 |
| Extrinsic memory: | | 204800 | bits |
| | | 634663.69 | um\hat{ }2 |

| | | | |
|---|---|---|---|
| Total | Iterative Decoder | 4341581.431 | um\hat{ }2 |
| | | 4.34 | mm\hat{ }2 |

| | | |
|---|---|---|
| RS decoder area | 0.5 | mm\hat{ }2 |
| Outer interleaver: | 772310 | bits |
| | 2248781.95 | um\hat{ }2 |

| | | |
|---|---|---|
| Inner and Outer code total: | 7.09 | mm\hat{ }2 |

As will be apparent to those skilled in the art, the present invention provides a decoder architecture for turbo codes that can be implemented such that the clock rate of each of the M SISOs is only 1/M compared to that of the surrounding circuitry. Advantageously, the calculation of the state metrics in the SISO decoder can be implemented in such way as to save area and permit synthesis for high clock rates, while at the same time incurring only a small performance penalty (i.e. a small increase in BER). The calculation of the MIN* operation can be implemented in such a way as to save area and perform synthesis for high clock rates, while at the same time incurring only a small performance penalty (i.e. a small increase in BER).

In the embodiments described above, certain numbers of elements have been described, only as examples. For instance, although pairs of branch metric and state metric inputs are illustrated in the metric aggregators, each feeding an adder, with each pair of adders feeding a MIN or MIN* module in the codeword resolvers, the plurality of branch metric and state metric inputs can be of any number. Consequently, there need not necessarily be an even number of modules in the first level of the codeword resolvers, nor need there necessarily be an even number of inputs into the module in the second level of the codeword resolvers. Moreover, there could be a plurality of modules in the second level of the codeword resolvers, if desired. Of course, any increase in the number of modules would increase the size of the decoder, and likely also adversely affect the speed.

In summary, embodiments of the present invention include the following advantageous features: removing the NORM module from the parallel SISO architecture; using a hybrid approach in three different embodiments to improve performance; and modifying the MIN* operation to further improve performance.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. A soft input soft output (SISO) decoder for use in a hardware based turbo code decoder for receiving a sequence of samples representing a series of transmitted codewords selected from a known set of codewords, the SISO decoder comprising:
a metric aggregator for receiving and manipulating branch and state metric pairs, the branch and state metric pairs being related to the sequence of samples; and
a codeword resolver for resolving the manipulated branch and state metrics pairs to a codeword in the set, in accordance with an un-normalized likelihood relationship between the received branch and state metrics pairs and the known set of codewords.

2. The turbo decoder of claim 1 wherein the metric aggregator includes a plurality of D-type flip-flops and a plurality of adders, each D-type flip-flop of the plurality of D-type flip-flops for receiving one of the branch or state metrics in each pair, and each adder for receiving related branch and state metrics from an associated D-type flip-flop.

3. The turbo decoder of claim 2 wherein the D-type flip-flops are 8 bits in length.

4. The turbo decoder of claim 2 wherein the adders add 6 bit and 8 bit values.

5. The turbo decoder of claim 1 wherein the codeword resolver includes a hybrid architecture for state-metric calculation.

6. The turbo decoder of claim 1 wherein the codeword resolver includes two MIN* modules at a first level for receiving data associated with aggregated branch and state metrics, the outputs of two MIN* modules being provided to a third MIN* module.

7. The turbo decoder of claim 1 wherein the codeword resolver includes two MIN modules at a first level for receiving data associated with aggregated branch and state metrics, the outputs of two MIN modules being provided to a MIN* module.

8. The turbo decoder of claim 1 wherein the codeword resolver includes two MIN modules at a first level for receiving data associated with aggregated branch and state metrics, the outputs of two MIN modules being provided to a MIN* module, the MIN* module having a subtractor, a multiplexer controller, and a control module for performing correction operations in accordance with control signals received from the multiplexer controller.

9. The turbo decoder of claim 1 wherein the likelihood relationship is a likelihood that a particular un-normalized distance from the manipulated branch and state metrics pairs to the codeword, when compared to un-normalized distances to other codewords, indicates that the codeword is correct.

10. A MIN* operator for use in a soft input soft output (SISO) decoder associated with a turbo decoder, comprising:
a subtractor for receiving data to be decoded, the data associated with aggregated branch and state metrics;
a correction module for performing correction operations on data received from the subtractor, the correction module including a pair of lookup tables, and a plurality of multiplexers; and
a multiplexer controller for controlling operation of the plurality of multiplexers in the correction module to effect the correction operations in accordance with control signals generated by the multiplexer controller.

11. The MIN* operator of claim 10 wherein the pair of lookup tables includes a positive value lookup table and a negative value lookup table.

12. The MIN* operator of claim 10 wherein each of the pair of lookup tables has 4 entries.

13. The MIN* operator of claim 10 wherein the multiplexer controller includes a plurality of control units.

14. The MIN* operator of claim 13 the plurality of control units in the multiplexer controller is equal to the plurality of multiplexers in the correction module.

15. A method of soft input soft output decoding for resolving a sequence of samples to a codeword in a known set of codewords, the method comprising:
receiving a plurality of branch metric and state metric pairs related to the sequence of samples;
aggregating related branch and state metric pairs; and
resolving the aggregated branch and state metric pairs to the codeword in the set in accordance with an un-normalized likelihood relationship between the aggregated branch and state metrics pairs and the known set of codewords.
